(19) United States
(12) Patent Application Publication
(10) Pub. No.: US 2025/0334627 A1
(43) Pub. Date: Oct. 30, 2025

(54) SEMICONDUCTOR TEST APPARATUS AND METHOD OF MANUFACTURING SEMICONDUCTOR DEVICE

(71) Applicant: Renesas Electronics Corporation, Tokyo (JP)

(72) Inventor: Fukumi UNOKUCHI, Tokyo (JP)

(21) Appl. No.: 19/084,031

(22) Filed: Mar. 19, 2025

(30) Foreign Application Priority Data
Apr. 30, 2024 (JP) 2024-073585

(51) Int. Cl. G01R 31/28; G01R 1/067; G01R 3/00

(52) U.S. Cl. CPC G01R 31/2863; G01R 1/06738; G01R 3/00

(57) ABSTRACT

To provide a semiconductor test apparatus capable of improving the conductivity between a probe pin and an external terminal of a semiconductor device while suppressing the breakage of the probe pin. The semiconductor test apparatus comprises a socket base, a probe guide, and the probe pin. The socket base has a first surface and a second surface opposite the first surface in a first direction. A first opening penetrating the socket base along the first direction is provided. The probe guide is movably disposed within the first opening along the first direction. The probe guide has a first end that protrudes from the first surface when moved from the second surface to the first surface along the first direction, and a second end opposite the first end. A second opening penetrating the probe guide along the first direction is provided.

### CROSS-REFERENCE TO RELATED APPLICATIONS

The disclosure of Japanese Patent Application No. 2024-073585 filed on Apr. 30, 2024, including the specification, drawings and abstract is incorporated herein by reference in its entirety.

### BACKGROUND

This disclosure relates to a semiconductor test apparatus and a method of manufacturing a semiconductor device.

Japanese Patent Laid-Open No. 2019-219350 (Patent Document 1) discloses a test apparatus. The test apparatus includes an outer plunger and a probe pin. The outer plunger is cylindrical and extends along a first direction. An opening is formed in the outer plunger, penetrating it along the first direction. The outer plunger has a first end and a second end, which is the opposite end of the first end, in the first direction. The probe pin extends along the first direction and has a third end in the first direction. The probe pin includes a tip portion located at the third end. The tip portion of the probe pin is inserted into the opening of the outer plunger from the second end, with the third end protruding from the first end. In the test apparatus of Patent Document 1, testing of the semiconductor device is conducted by the tip portion of the probe pin contacting an external terminal of a to-be-inspected device.

### SUMMARY

In the test apparatus described in Patent Document 1, a plurality of protrusions is formed on the tip portion of the probe pin, and each of the plurality of protrusions contacts the external terminal of the semiconductor device. As a result, the load acting between one protrusion and the external terminal of the semiconductor device is reduced, which may lead to insufficient electrical conduction between the probe pin and the external terminal of the to-be-inspected device. Other problems and novel features will become apparent from the description of this specification and the accompanying drawings.

A semiconductor test apparatus of this disclosure includes a socket base, a probe guide, and a probe pin. The socket base has a first surface and a second surface, which is the opposite surface of the first surface, in the first direction. A first opening is provided in the socket base, penetrating it along the first direction. The probe guide is movably disposed within the first opening along the first direction. The probe guide has a first end that protrudes from the first surface when moved along the first direction from the second surface to the first surface, and a second end, which is the opposite end of the first end. A second opening is provided in the probe guide, penetrating it along the first direction. The probe pin extends along the first direction and has a tip portion located at the third end, which is the end in the first direction. An outer diameter of the tip portion decreases as it approaches the third end. The tip portion is inserted into the second opening from the second end so that the third end can protrude from the first end. When the tip portion contacts an external terminal of the to-be-inspected device, the probe guide and the probe pin are integrated.

According to the semiconductor test apparatus of this disclosure, it is possible to improve the conductivity between the probe pin and the external terminal of the to-be-inspected device while suppressing the breakage of the probe pin.

### BRIEF DESCRIPTION OF THE DRAWINGS

FIG. 1 is a cross-sectional view of a semiconductor test apparatus TAP.

FIG. 2 is a cross-sectional view of a probe PRO.

FIG. 3 is a schematic side view of the inspection apparatus using the semiconductor test apparatus TAP.

FIG. 4 is a manufacturing process diagram of a semiconductor device SDEV.

FIG. 5 is a first explanatory view illustrating the effect of the semiconductor test apparatus TAP.

FIG. 6A is a second explanatory view illustrating the effect of the semiconductor test apparatus TAP.

FIG. 6B is a third explanatory view illustrating the effect of the semiconductor test apparatus TAP.

FIG. 7A is a schematic first cross-sectional view of a modified example of the semiconductor test apparatus TAP.

FIG. 7B is a schematic second cross-sectional view of a modified example of the semiconductor test apparatus TAP.

### DETAILED DESCRIPTION

Details of the embodiments of the present disclosure will be described with reference to the drawings. In the following drawings, the same reference numerals are used for the same or corresponding parts, and redundant descriptions will not be repeated. The testing apparatus according to the embodiment is referred to as the testing apparatus TAP.

### (Configuration of the Testing Apparatus)

A configuration of the testing apparatus TAP will be described below.

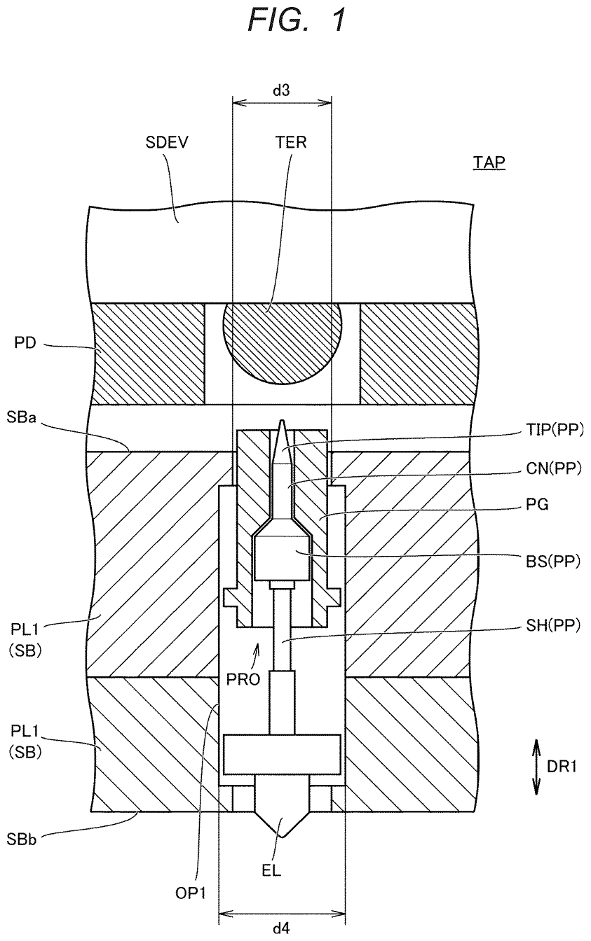

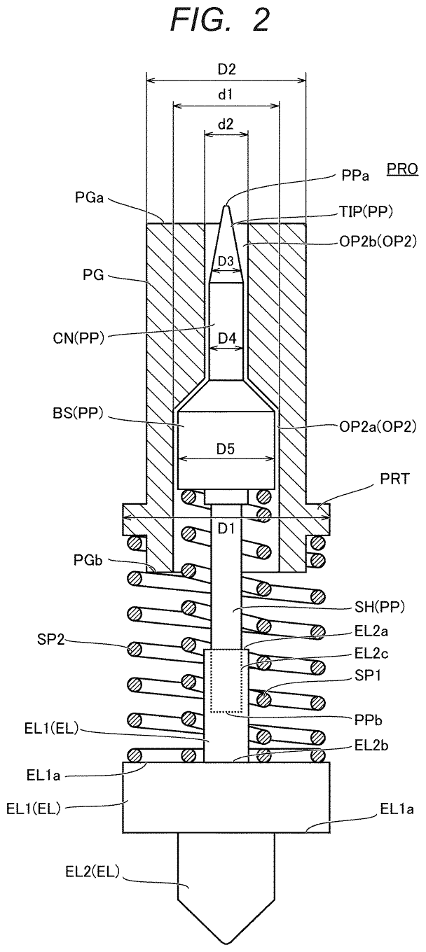

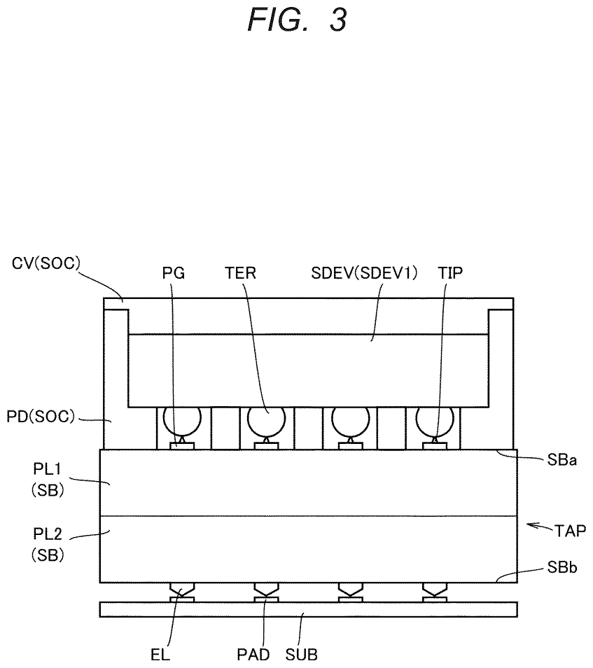

FIG. 1 is a cross-sectional view of the testing apparatus TAP. FIG. 2 is a cross-sectional view of a probe PRO. As shown in FIGS. 1 and 2, the testing apparatus TAP includes a socket base SB and a probe PRO. Note that the testing apparatus TAP may include a plurality of probes PRO (see FIG. 3). The testing apparatus TAP is a semiconductor test apparatus for testing a semiconductor device SDEV having external terminals TER. The semiconductor device SDEV includes an integrated circuit, and the external terminals TER are electrically connected to the integrated circuit. The external terminals TER are, for example, solder balls.

The socket base SB has a first surface SBa and a second surface SBb in a first direction DR1. The second surface SBb is the opposite surface of the first surface SBa. The socket base SB is arranged such that the first surface SBa faces the external terminals TER. A first opening OP1 is provided in the socket base SB. The first opening OP1 extends along the first direction DR1 and penetrates the socket base SB. If the testing apparatus TAP has the 8 probes PRO, the socket base SB will have a plurality of first openings OP1. The socket base SB includes, for example, a first plate member PL1 and a second plate member PL2. The first plate member PL1 overlaps the second plate member PL2. The first plate member PL1 forms the first surface SBa, and the second plate member PL2 forms the second surface SBb.

The probe PRO includes a probe guide PG, a probe pin PP, an electrode EL, a first spring SP1, and a second spring SP2. The probe PRO is movable along the first direction DR1 within the first opening OP1. The stroke width within which the probe PRO can move inside the first opening OP1 is, for example, between 450 micrometers and 500 micrometers.

The probe guide PG is arranged within the first opening OP1. The probe guide PG is movable along the first direction DR1. The probe guide PG is cylindrical, extending along the first direction DR1. The probe guide PG has a first end PGa and a second end PGb in the first direction DR1. When the probe guide PG is moved from the second surface SBb towards the first surface SBa along the first direction DR1, the first end PGa protrudes from the first surface SBa. The second end PGb is the opposite end of the first end PGa. A second opening OP2 is formed in the probe guide PG. The second opening OP2 penetrates the probe guide PG along the first direction DR1.

The second opening OP2 includes a first portion OP2a and a second portion OP2b. The first portion OP2a extends from the second end PGb towards the first end PGa. The second portion OP2b extends from the first portion OP2a to the first end PGa. An inner diameter of the first portion OP2a is referred to as a first inner diameter d1, and an inner diameter of the second portion OP2b is referred to as a second inner diameter d2. The first inner diameter d1 is, for example, constant. However, at the end of the second portion OP2b, the first inner diameter d1 decreases as it approaches the second portion OP2b. Also, at the connection point between the first portion OP2a and the second portion OP2b, the first inner diameter d1 becomes equal to the second inner diameter d2. The second inner diameter d2 is, for example, constant.

A protrusion PRT is formed on the outer circumferential surface of the probe guide PG. The protrusion PRT extends in the circumferential direction, that is, along the circumference centered on a central axis of the probe guide PG when viewed along the first direction DR1. An outer diameter of the probe guide PG is maximum at the protrusion PRT. An inner diameter of the first opening OP1 at the end on the first surface SBa is referred to as a third inner diameter d3, and an inner diameter of the first opening OP1 between the end on the first surface SBa and the end on the second surface SBb is referred to as a fourth inner diameter d4. The outer diameter of the probe guide PG at the protrusion PRT is referred to as a first outer diameter D1, and the outer diameter of the probe guide PG other than at the protrusion PRT is referred to as a second outer diameter D2. The third inner diameter d3 is smaller than the first outer diameter D1 and larger than the second outer diameter D2. Therefore, the portion of the probe guide PG located between the protrusion PRT and the first end PGa can protrude from the first surface SBa.

The probe pin PP extends along the first direction DR1. The probe pin PP has a third end PPa and a fourth end PPb in the first direction DR1. The probe pin PP includes a tip portion TIP, a base end BS, a connecting portion CN, and a shaft SH. The probe pin PP is formed of a conductive material.

The tip portion TIP is located at the third end PPa. The shape of the tip portion TIP is, for example, a cone. The shape of the tip portion TIP is, for example, a polyhedral cone, a conical shape, or a cone with a parabola or hyperbola as its generatrix. Note that even if the third end PPa is not a point, it is considered a cone. The base end BS is located further from the third end PPa than the tip portion TIP in the first direction DR1. The connecting portion CN is located between the tip portion TIP and the base end BS in the first direction DR1, connecting the tip portion TIP and the base end BS. The shaft SH is connected to the base end BS at one end in the first direction DR1 and forms the fourth end PPb at the other end in the first direction DR1.

An outer diameter of the tip portion TIP is referred to as a third outer diameter D3, and an outer diameter of the connecting portion CN is referred to as a fourth outer diameter D4. An outer diameter of the base end BS is referred to as a fifth outer diameter D5. The third outer diameter D3 decreases as it approaches the third end PPa. The maximum value of the third outer diameter D3 is, for example, between 150 micrometers and 160 micrometers. At the connection point between the tip portion TIP and the connecting portion CN, the third outer diameter D3 becomes equal to the fourth outer diameter D4. The fourth outer diameter D4 is, for example, constant. The fifth outer diameter D5 is, for example, constant. However, at the end of the connecting portion CN, the fifth outer diameter D5 decreases as it approaches the connecting portion CN. Also, at the connection point between the base end BS and the connecting portion CN, the fifth outer diameter D5 becomes equal to the fourth outer diameter D4. That is, the fourth outer diameter D4 is equal to a maximum value of the third outer diameter D3 and a minimum value of the fifth outer diameter D5. An outer diameter of the shaft SH is smaller than the fifth outer diameter D5.

A difference between the third inner diameter d3 and the second outer diameter D2 is, for example, smaller than a difference between the second inner diameter d2 and the fourth outer diameter D4. The value obtained by dividing the difference between the third inner diameter d3 and the second outer diameter D2 by 2 is, for example, between 7.5 micrometers and 17.5 micrometers. The value obtained by dividing the difference between the second inner diameter d2 and the fourth outer diameter D4 by 2 is, for example, between 17.5 micrometers and 32.5 micrometers.

The tip portion TIP is inserted into the second opening OP2 from the second end PGb so that the third end PPa protrudes from the first end PGa. The second inner diameter d2 is larger than the fourth outer diameter D4 but smaller than the maximum value of the fifth outer diameter D5. Therefore, when the probe pin PP is moved along the first direction DR1 so that the base end BS approaches the first end PGa, the base end BS gets caught in the second portion OP2b, preventing the base end BS from approaching the first end PGa any further. The tip portion TIP and the connecting portion CN have a length that allows the third end PPa to protrude from the first end PGa while the base end BS is caught in the second portion OP2b. The third end PPa protrudes from the first end PGa when the first end PGa is protruding from the first surface SBa. When a central axis of the probe pin PP is inclined with respect to the first direction DR1, it contacts an inner wall surface of the second opening OP2.

The electrode EL comprises a support portion EL1, a shaft portion EL2, and a contact portion EL3. The support portion EL1 has a third surface EL1a and a fourth surface EL1b in the first direction DR1. The fourth surface EL1b is the opposite surface of the third surface EL1a. The shaft portion EL2 extends from the third surface EL1a along the first direction DR1. The shaft portion EL2 has a fifth end EL2a and a sixth end EL2b in the first direction DR1. The sixth end EL2b is the opposite end of the fifth end EL2a. The shaft portion EL2 is connected to the support portion EL1 (third surface EL1a) at the sixth end EL2b. A hole EL2c is provided at the fifth end EL2a. The hole EL2c extends from the fifth end EL2a towards the sixth end EL2b along the first direction DR1. The contact portion EL3 extends from the fourth surface EL1b along the first direction DR1. The electrode EL is formed of a conductive material.

The shaft portion EL2 is inserted into the hole EL2c in a slidable manner along an inner wall surface of the hole EL2c in the first direction DR1. This allows the probe pin PP and the electrode EL to be electrically connected to each other. The first spring SP1 connects the base end BS and the support portion EL1, surrounding the shaft portion EL2. The second spring SP2 connects the protrusion PRT and the support portion EL1, surrounding the first spring SP1 and the shaft portion EL2.

The first spring SP1 generates an elastic force to move the base end BS and the support portion EL1 away from each other when the distance between the base end BS and the support portion EL1 decreases. The second spring SP2 generates an elastic force to move the probe guide PG and the support portion EL1 closer to each other. Thus, the probe pin PP and the probe guide PG are integrated by the elastic force of the second spring SP2. The spring constant of the first spring SP1 is, for example, greater than that of the second spring SP2.

FIG. 3 is a schematic side view of the inspection apparatus using the semiconductor test apparatus TAP. As shown in FIG. 3, the inspection apparatus includes a substrate SUB in addition to the semiconductor test apparatus TAP. A pad PAD is provided on the surface of the substrate SUB. A power supply is connected to the substrate SUB. When the electrode EL contacts the pad PAD and the probe pin PP (tip portion TIP) contacts the external terminal TER, a current flow through the semiconductor device SDEV via the probe PRO. This allows for the inspection of the semiconductor device SDEV.

### (Manufacturing Method of the Semiconductor Device)

A manufacturing method of the semiconductor device SDEV is described below.

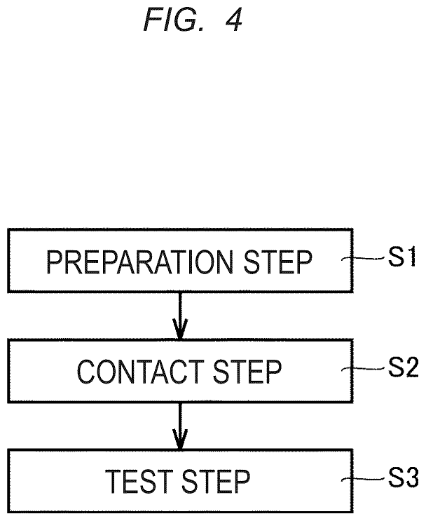

FIG. 4 is a flow chart of the manufacturing method of the semiconductor device SDEV. As shown in FIG. 4, the manufacturing method of the semiconductor device SDEV includes a preparation step S1, a contact step S2, and a test step S3. In the preparation step S1, a semiconductor device SDEV1 is prepared. The configuration of the semiconductor device SDEV1 is similar to that of the semiconductor device SDEV, except that the external terminal TER is not deformed, as it has not undergone the contact step S2.

In the contact step S2, the probe pin PP and the external terminal TER are electrically connected by deforming the external terminal TER through contact with the tip portion TIP. Specifically, first, the semiconductor test apparatus TAP is placed on the substrate SUB such that the second surface SBb faces the substrate SUB and the electrode EL faces the pad PAD. Second, the semiconductor device SDEV1 is housed in a socket SOC. The socket SOC includes a pedestal PD and a cover CV. The semiconductor device SDEV1 is placed on the pedestal PD such that the external terminal TER is exposed through an opening provided in a bottom wall of the pedestal PD. After the semiconductor device SDEV1 is placed on the pedestal PD, the pedestal PD is closed with the cover CV.

Third, the socket SOC is placed on the semiconductor test apparatus TAP such that the first surface SBa faces the external terminal TER (so that the external terminal TER and the tip portion TIP face each other). Fourth, the socket SOC is pressed towards the semiconductor test apparatus TAP. This causes the tip portion TIP and the external terminal TER to contact each other, reducing the distance between the base end BS and the support portion EL1. As a result, the tip portion TIP is pressed against the external terminal TER by the elastic force of the first spring SP1, deforming the external terminal TER (an indentation is formed on the surface of the external terminal TER), and the tip portion TIP and the external terminal TER are electrically connected. This transforms the semiconductor device SDEV1 into the semiconductor device SDEV. The load applied from the tip portion TIP to the external terminal TER is, for example, 0.27N (28 gf) or more and less than 0.31N (32 gf). At this time, the contact portion EL3 is also pressed against the pad PAD, and the pad PAD and the electrode EL are electrically connected.

In the test step S3, a current flows from the substrate SUB to the semiconductor device SDEV via the probe PRO, allowing for the inspection of the semiconductor device SDEV. Thus, the semiconductor device SDEV is manufactured.

### (Effect of Semiconductor Test Apparatus TAP)

The effect of the semiconductor test apparatus TAP is described below.

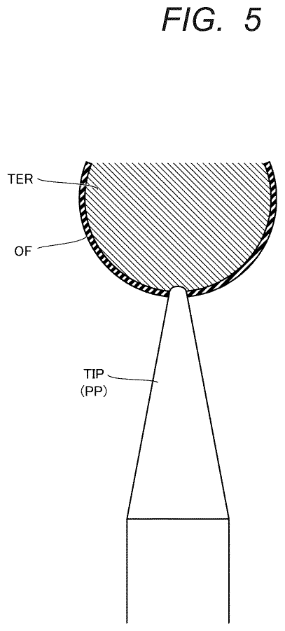

FIG. 5 is the first explanatory diagram illustrating the effect of the semiconductor test apparatus TAP. As shown in FIG. 5, an oxide film OF is formed on the surface of the external terminal TER. Therefore, if the oxide film OF is not destroyed by contact with the tip portion TIP, the probe pin PP and the external terminal TER will not be electrically connected. In this regard, the semiconductor test apparatus TAP has a needle-shaped tip portion TIP, which contacts the oxide film OF at a single point, increasing the load at the contact point with the oxide film OF, making it easier to destroy the oxide film OF.

When the tip portion TIP of the probe pin PP contacts the oxide film OF at the plurality of protrusions, the load per contact point decreases, making it harder to destroy the oxide film OF. As a result, in this case, the period during which stable testing is possible becomes shorter compared to the semiconductor test apparatus TAP where the tip portion TIP contacts the oxide film OF at a single point. Additionally, when the tip of the probe pin PP has a plurality of protrusions, debris tends to accumulate in the recesses between adjacent the plurality of protrusions, necessitating regular cleaning.

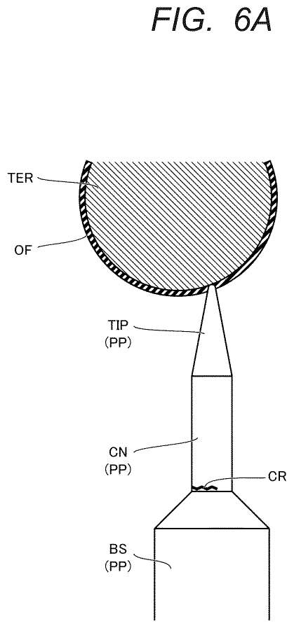

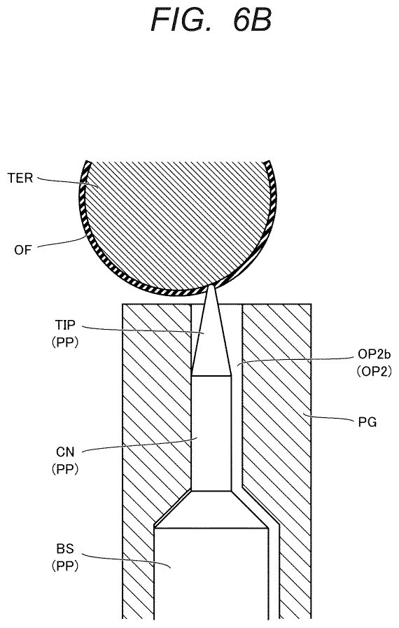

FIG. 6A is the second explanatory diagram illustrating the effect of the semiconductor test apparatus TAP. As shown in FIG. 6A, the tip portion TIP may contact the external terminal TER with its center offset from the center of the external terminal TER. If the semiconductor test apparatus TAP does not have the probe guide PG, a load is applied to the connection point between the connecting portion CN and the base end BS, raising concerns that a crack CR may occur at this point, causing the probe pin PP to break.

FIG. 6B is the third explanatory diagram illustrating the effect of the semiconductor test apparatus TAP. As shown in FIG. 6B, the semiconductor test apparatus TAP includes the probe guide PG, and since the probe guide PG is integrated with the probe pin PP, even if the tip portion TIP contacts the external terminal TER with its center offset from the center of the external terminal TER as described above, the probe pin PP (connecting portion CN) is supported by the inner wall surface of the second opening OP2, reducing the load applied to the connection point between the connecting portion CN and the base end BS. Thus, according to the semiconductor test apparatus TAP, it is possible to improve the conductivity between the probe pin PP and the external terminal TER while suppressing the breakage of the probe pin PP. This, in turn, contributes to extending the lifespan of the probe PRO. Even if the central axis of the probe pin PP is inclined with respect to the first direction DR1, the probe pin PP is supported by the inner wall surface of the second opening OP2, similarly suppressing the breakage of the probe pin PP.

When the semiconductor device SDEV1 is, for example, a BGA package, the number of the external terminals TER increases. As a result, when the tip of a probe pin has the plurality of protrusions, a very large load must be applied to the socket SOC to increase the load per contact point, making it difficult to handle with a standard inspection apparatus. On the other hand, in the semiconductor test apparatus TAP, since the tip portion TIP contacts the external terminal TER at a single point, even when the number of the external terminals TER is large, it is possible to increase the load per contact point without applying an excessive load to the socket SOC.

When the difference between the third inner diameter d3 and the second outer diameter D2 is smaller than the difference between the second inner diameter d2 and the fourth outer diameter D4, it is possible to suppress the positional deviation within the first opening OP1 of the probe PRO while suppressing the breakage of the probe pin PP.

As the third outer diameter D3 decreases, the tip portion TIP becomes sharper, reducing the contact area between the tip portion TIP and the external terminal TER, thereby improving the conductivity between the probe pin PP and the external terminal TER. On the other hand, as the third outer diameter D3 decreases, the fourth outer diameter D4 also decreases, making it easier for the probe pin PP to break at the connection point between the connecting portion CN and the base end BS. Therefore, by setting the maximum value of the third outer diameter D3 to 150 micrometers or more and less than 160 micrometers, it is possible to achieve both the suppression of the probe pin PP breakage and the improvement of conductivity with the external terminal TER.

### Modified Example

The semiconductor test apparatus TAP according to the modified example is described below.

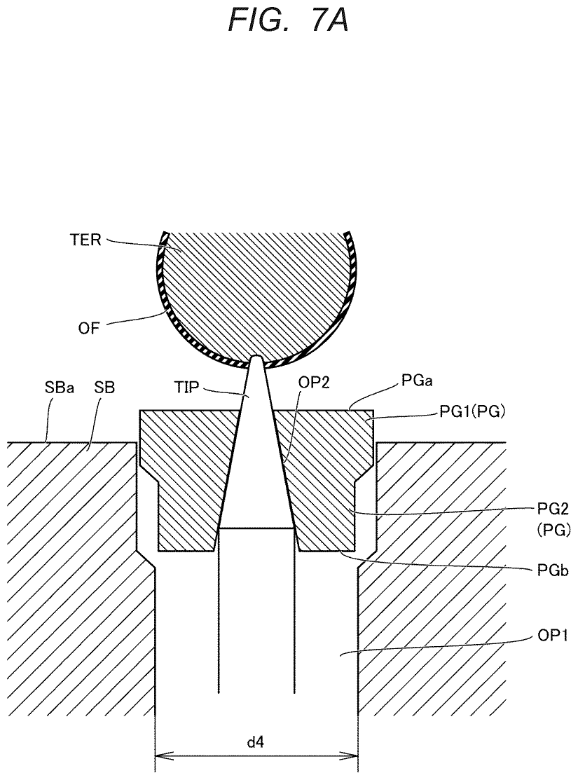

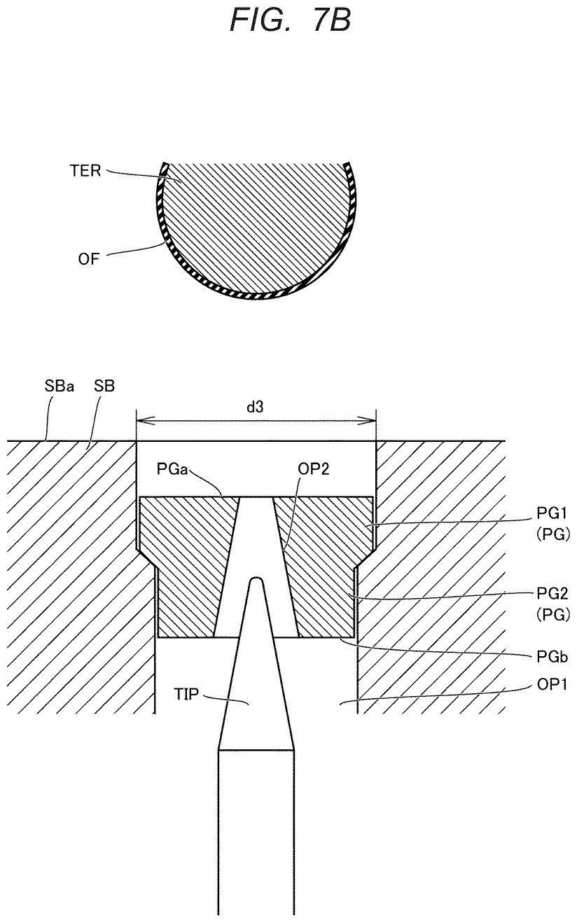

FIG. 7A is a schematic first cross-sectional view of the semiconductor test apparatus TAP according to the modified example. FIG. 7B is a schematic second cross-sectional view of the semiconductor test apparatus TAP according to the modified example. As shown in FIGS. 7A and 7B, the probe guide PG comprises a first portion PG1 and a second portion PG2. The first portion PG1 extends from the first end PGa towards the second end PGb along the first direction DR1. The second portion PG2 extends in the first direction DR1 from the first portion PG1 to the second end PGb.

The third inner diameter d3 is larger than the fourth inner diameter d4. An outer diameter of the first portion PG1 is larger than an outer diameter of the second portion PG2. The outer diameter of the first portion PG1 is smaller than the third inner diameter d3 and larger than the fourth inner diameter d4. An inner diameter of the second opening OP2 decreases as it approaches from the second end PGb to the first end PGa. Therefore, when the probe pin PP moves in the direction from the second surface SBb to the first surface SBa, the probe pin PP and the probe guide PG move together, but when the probe pin PP moves in the direction from the first surface SBa to the second surface SBb, the movement of the probe guide PG is restricted by the step on an inner wall surface of the first opening OP1. That is, when the tip portion TIP is in contact with the external terminal TER, the probe guide PG becomes integrated with the probe pin PP (tip portion TIP) (see FIG. 7A), while when the tip portion TIP is not in contact with the external terminal TER, the probe guide PG is separated from the probe pin PP (see FIG. 7B).

In this case, since the probe guide PG becomes integrated with the probe pin PP (tip portion TIP) when the tip portion TIP is in contact with the external terminal TER, it is possible to suppress the breakage of the probe pin PP. Also, in this case, the second spring SP2 becomes unnecessary, making it possible to reduce the number of components constituting the probe PRO.

Although the invention made by the present inventors has been described in detail based on the embodiments, it is needless to say that the present invention is not limited to the above-described embodiments and can be variously modified without departing from the gist thereof.

What is claimed is:

1. A semiconductor test apparatus comprising:
a socket base;
a probe guide; and
at least one probe pin, wherein
the socket base has a first surface and a second surface opposite to the first surface in a first direction,
the socket base has at least one first opening penetrating the socket base along with the first direction,
the probe guide is movably disposed in the first opening along with the first direction,
the probe guide has a first end protruding from the first surface when the probe guide is moved from the second surface to the first surface along with the first direction, and a second end opposite to the first end,
the probe guide has a second opening penetrating the probe guide along with the first direction,
the probe pin extends along the first direction and has a tip portion disposed at a third end in the first direction,
an outer diameter of the tip portion decreases as it approaches the third end,
the tip portion is inserted in the second opening from the second end so that the third end is able to protrude from the first end, and
when the tip portion contacts an external terminal of a to-be-inspected device, the probe guide and the probe pin are integrated.

2. The semiconductor test apparatus according to claim 1, wherein
a difference between an inner diameter of the first opening and an outer diameter of the probe guide is smaller than a difference between an inner diameter of the second opening and an outer diameter of the probe pin.

3. The semiconductor test apparatus according to claim 1, wherein
a value obtained by dividing by 2 a difference between an inner diameter of the first opening and an outer diameter of the probe guide is 7.5 micrometers or more and less than 17.5 micrometers, and
a value obtained by dividing by 2 a difference between an inner diameter of the second opening and an outer diameter of the probe pin is 17.5 micrometers or more and less than 32.5 micrometers.

4. The semiconductor test apparatus according to claim 1, further comprising:
a base end; and
a connecting portion, wherein
the connecting portion connects the tip portion and the base end, and
a maximum value of an outer diameter of the tip portion is 150 micrometers or more and less than 160 micrometers.

5. The semiconductor test apparatus according to claim 1, wherein
a shape of the tip portion is cone.

6. The semiconductor test apparatus according to claim 1, wherein
the third end protrudes from the first end in a state where the third end protrudes from the first surface.

7. The semiconductor test apparatus according to claim 1, wherein
the probe pin has a base end and a connecting portion,
the connecting portion connects the tip portion and the base end, and
the connecting portion contacts an inner wall surface of the second opening when a central axis of the probe pin is inclined with respect to the first direction.

8. The semiconductor test apparatus according to claim 1, wherein
the probe pin has a base end and a connecting portion,
the connecting portion connects the tip portion and the base end,
the second opening has a first portion extending from the second end toward the first end, and a second portion extending from the first portion to the first end, and
an inner diameter of the second portion is larger than an outer diameter of the connecting portion and smaller than a maximum value of an outer diameter of the base end.

9. The semiconductor test apparatus according to claim 1, wherein
the probe pin and the probe guide are movable at a distance of 450 micrometers or more and 500 micrometers or less in the first direction.

10. The semiconductor test apparatus according to claim 1, wherein
the at least one probe pin is a plurality of probe pins, and
the socket base has a plurality of first openings.

11. The semiconductor test apparatus according to claim 1, wherein
a movement of the probe guide along the first direction from the first surface to the second surface is restricted by the first opening, thereby the probe guide separates from the probe pin, when the probe pin moves from the first surface to the second surface along the first direction.

12. A manufacturing method of a semiconductor device, comprising the step of:
(a) preparing a to-be-inspected device having an integrated circuit and an external terminal electrically connected to the integrated circuit;
(b) preparing a semiconductor test apparatus having a socket base, a probe guide, and a probe pin; and
(c) for electrically contacting to the integrated circuit, deforming the external terminal by contacting the probe pin, wherein
the socket base has a first surface in a first direction and the first surface is disposed to face the external terminal,
the socket base has a first opening penetrating the socket base along with the first direction,
the probe guide is disposed in the first opening,
a shape of the probe guide is cylindrical extending along the first direction,
the probe guide has a second opening penetrating the probe guide along with the first direction,
the probe guide has a first end and a second end opposite to the first end in the first direction,
the probe pin extends along the first direction and has a third end in the first direction,
the probe pin has a tip portion located at the third end,
an outer diameter of the tip portion decreases as it approaches the third end,
the tip portion is inserted in the second opening from the second end so that the third end is able to protrude from the first end, and
when the tip portion contacts the external terminal, the probe guide and the probe pin are integrated.

13. The manufacturing method of the semiconductor device according to claim 12, wherein
a difference between an inner diameter of the first opening and an outer diameter of the probe guide is smaller than a difference between an inner diameter of the second opening and an outer diameter of the probe pin.

14. The manufacturing method of the semiconductor device according to claim 12, wherein
a value obtained by dividing by 2 a difference between an inner diameter of the first opening and an outer diameter of the probe guide is 7.5 micrometers or more and less than 17.5 micrometers, and
a value obtained by dividing by 2 a difference between an inner diameter of the second opening and an outer diameter of the probe pin is 17.5 micrometers or more and less than 32.5 micrometers.

15. The manufacturing method of the semiconductor device according to claim 12, wherein
the probe pin has a base end and a connecting portion, the connecting portion connects the tip portion and the base end, and
a maximum value of the outer diameter of the tip portion is 150 micrometers or more and less than 160 micrometers.

16. The manufacturing method of the semiconductor device according to claim 12, wherein
a shape of the tip portion is cone.

17. The manufacturing method of the semiconductor device according to claim 12, wherein
the third end protrudes from the first end in a state where the third end protrudes from the first surface.

18. The manufacturing method of the semiconductor device according to claim 12, wherein
the probe pin has a base end and a connecting portion,
the connecting portion is disposed between the tip portion and the base end, and
the connecting portion contacts an inner wall surface of the second opening when a central axis of the probe pin is inclined with respect to the first direction.

19. The manufacturing method of the semiconductor device according to claim 12, wherein
the probe pin has a base end and a connecting portion,
the connecting portion is disposed between the tip portion and the base end,
an outer diameter of the connecting portion is equal to or greater than a maximum value of an outer diameter of the base end and equal to or less than a maximum value of the outer diameter of the tip portion,
the second opening has a first portion extending from the second end toward the first end, and a second portion extending from the first portion to the first end, and
an inner diameter of the second portion is larger than the outer diameter of the connecting portion and smaller than a maximum value of the outer diameter of the base end.

20. The manufacturing method of the semiconductor device according to claim 12, wherein
the tip portion contacts the external terminal with a load of 0.27N or more and less than 0.31N.
